(19) United States
(12) Patent Application Publication
(10) Pub. No.: US 2010/0327119 A1
(43) Pub. Date: Dec. 30, 2010

(54) Satellite communication system, infrastructure and method of providing same

(76) Inventors: Edward D. HOROWITZ, New York, NY (US); Mark J. Piegza, New York, NY (US)

Correspondence Address: King and Spalding LLP, 1700 Pennsylvania Ave, NW, Suite 200, Washington, DC, 20006, US

(21) Appl. No.: 12/825,759

(22) Filed: Jun. 29, 2010

Related U.S. Application Data
(60) Provisional application No. 61/221,938, filed on Jun. 30, 2009.

(51) Int. Cl. B64G 1/10; H05K 13/00

(52) U.S. Cl. 244/173.1; 29/592.1

(57) ABSTRACT

A satellite communication system, infrastructure, and method of providing same, involves inventorying certain types of pre-selected communication satellite payload modules and communication satellite bus modules based on analysis of anticipated communication satellite needs and providing each payload and bus module with a pre-configured standard interface coupling. When communication satellite parameters for a customer are received, a selection is made of one or more of the inventoried payload modules and also of the inventoried communication satellite bus module that is sized and configured to accommodate the selected payload module or modules. The selected payload module or modules are coupled to the selected bus module via the standard interface coupling, and the selected bus module is, in turn, coupled to a launch vehicle.

### CROSS-REFERENCE TO RELATED APPLICATIONS

This application is related to and claims the benefit of priority under one or more of 35 U.S.C 119 and/or 35 U.S.C 120 to U.S. Provisional Application 61/221,938 entitled “Satellite Communication System, Infrastructure and Method of Providing Same” filed Jun. 30, 2009 and incorporated by reference herein.

### FIELD OF INVENTION

Generally, the invention is directed to an improved satellite communication system and infrastructure. More particularly, the invention is directed to a satellite system and infrastructure having a modular bus/payload design to accommodate a range of communication needs and frequencies.

### BACKGROUND OF THE INVENTION

Large satellite customers, such as the United States Government (“USG”), rely on satellite technology to provide superior communication ability to its geographically dispersed forces. The USG currently uses two methods to procure satellite communications capability: (i) building and operating its own systems (“Milsatcom”) and (ii) leasing capacity from commercial satellite operators (“Commercial Satcom”). Each of these solutions has shortcomings which may prevent rapid and cost-effective deployment.

For example, Milsatcom has a complex procurement process and requires significant up-front investment from the Department of Defense (“DoD”). Milsatcom is also prone to late delivery and cost over-runs and does not support the need for increased satellite demand and rapid deployment in crises.

Since Milsatcom cannot satisfy the growing need for additional capacity, the USG is receiving significant communication capacity from Commercial Satcom. Commercial Satcom operates on its own set of frequencies and is not compatible with the USG installed base of radio equipment and network control systems. While Commercial Satcom offers a short development cycle and significant diversity of capacity in space, the lack of compatibility with DoD's own existing radio channel map and operational infrastructure requires the DoD to deploy an expensive customized parallel network and set of radio equipment. In addition, currently, all leading providers of Commercial Satcom services are owned by foreign entities, creating inherent conflicts when dealing with the DoD.

Each of the aforementioned solutions must provide both wideband and narrowband capability to fit the need of different USG end users. Typically, such satellites include a bus and payload. The bus provides support and control functionality and can include a number of sub-systems including structural sub-systems, telemetry sub-systems, power sub-systems, thermal control sub-systems and attitude and orbit sub-systems. The payload includes antennas, amplifiers and transponders which receive a communication signal, amplify and sort the signal and direct the signal through input/output signal multiplexers to the proper downlink antennas for retransmission. The composition and size of the bus and payload are typically dictated by the type of communication frequency band utilized for the particular communication need and the channel capacity. For instance, a narrowband UHF payload will require different antennae and transponders than a wideband X or Ka band payload.

Traditionally, the bus and payload were not modular and when changing one bus for another, modifications to the bus or payload would need to be made in order to provide a connection between the two thus resulting in greater expense and delay in the manufacturing process since both the bus and/or payload must be specifically tailored to accept a different payload depending on the use of the satellite.

### SUMMARY OF THE INVENTION

Embodiments of the invention provide satellite communication systems, infrastructure, and methods of providing same with the advantage of enabling privatization of military satellite communications finance for the U.S. government. For example, embodiments of the invention propose providing military satellite communications operating on military frequencies for the government on a fee-for-service basis that can include an option to purchase. Further embodiments of the invention involve actually building such satellite communication systems, which the government now typically builds for itself, on a privately financed basis and providing such systems to the government as a service.

Typically, a request for proposal by the U.S. Navy on a communications satellite may indicate that the Navy needs to have the satellite in service within a particular period, such as thirty months. Aspects of embodiments of the invention include the modularization and standardization of satellite buses and payloads that enables a plug-and-play operation that can reduce the time to market from traditionally twenty-four to thirty-two months or more down to a short period of as little as thirty days.

Embodiments of the invention propose a communication satellite assembly that includes, for example, one or more communication satellite payload modules selected according to pre-defined communication satellite parameters, such as orbit and frequency band parameters compatible with a terrestrial infrastructure used by a governmental entity, from an inventory of communication satellite payload modules.

In embodiments of the invention, the inventory of communication satellite payload modules consists at least in part of three different types of communication satellite payload modules for three different communication satellite frequency band types, and each of the inventoried communication satellite payload modules is provided with a pre-configured standard interface coupling.

The communication satellite assembly for embodiments of the invention also includes, for example, one of two sizes of communication satellite bus modules that is configured to accommodate the one or more selected communication satellite payload modules and that is also selected according to the pre-defined communication satellite parameters from an inventory of communication satellite bus modules.

According to embodiments of the invention, the inventory of communication satellite bus modules consists at least in part of a plurality of one of the two sizes of communication satellite bus modules configured to accommodate one or more of the three different types of communication satellite payload modules. The inventory of communication satellite bus modules also consists at least in part of a plurality of the other of the two sizes of communication satellite bus modules configured to accommodate one or more of the other of the three different types of communication satellite payload modules. Moreover, each of the inventoried communication satellite bus modules is likewise provided with the pre-configured standard interface coupling.

In embodiments of the invention, the one or more selected communication satellite payload modules are coupled to the selected communication satellite bus module via the pre-configured standard interface coupling, and in turn, the selected communication satellite bus module is coupled to a communication satellite launch vehicle for deployment in orbit according to the communication satellite parameters.

Each of said inventoried communication satellite payload modules for embodiments of the invention includes, for example, one or more antennas, amplifiers and transponders, and the three different types of communication satellite payload modules can include communication satellite payload module types for each of three or more different communication satellite frequency band types consisting of one or more wideband frequency payload types, one or more narrow band frequency payload types, and a combination of one or more wideband and one or more narrow band frequency payload types.

Each of the inventoried communication satellite bus modules for embodiments of the invention includes, for example, a structural sub-system, a telemetry sub-system, power sub-systems, a thermal control sub-system, and an attitude and orbit sub-system. In embodiments of the invention, one of the two sizes of communication satellite bus modules is configured to accommodate one or more communication satellite payload modules for either a communication satellite wideband frequency type payload or a communication satellite narrow band frequency type payload and the other of the two sizes of communication satellite bus modules is configured to accommodate one or more communication satellite payload modules for each of a communication satellite wideband frequency type and a communication satellite narrow band frequency type.

The communication satellite assembly for embodiments of the invention includes, for example, a communication satellite bus control device, such as a first computing device in wireless communication with the selected communication satellite bus module, for managing the communication satellite bus module. The communication satellite assembly also includes a communication satellite payload module control device, such as a second computing device in wireless communication with the selected communication satellite payload module for managing the communication satellite payload module. In embodiments of the invention, both of the control devices can be delivered to the possession of a communication satellite customer for exclusive management control of the selected communication satellite bus and payload modules.

The communication satellite assembly for embodiments of the invention can also include, for example, one or more video cameras mounted on an exterior of the selected communication satellite bus module for providing a real time view of the environment surrounding the selected communication satellite bus module. In addition, the communication satellite assembly for embodiments of the invention can be provided with one or more refueling valves allowing direct access to a satellite fuel tank for refueling, and the refueling valves can, in turn, be provided with a locking mechanism to prevent inadvertent or unauthorized access to the satellite fuel tank.

Embodiments of the invention also propose a method of making a communication satellite assembly that involves, for example, analyzing, using a computer, data consisting at least in part of historical data regarding usage of communication satellite payload types to identify anticipated deployment needs for customers, such as a government entity, for three or more different communication satellite frequency band types.

According to embodiments of the invention a plurality of communication satellite payload modules consisting at least in part of three different types of communication satellite payload modules for the three or more different communication satellite frequency band types are inventoried. In addition, a plurality of communication satellite bus modules consisting at least in part of a plurality of one of two sizes of communication satellite bus module configured to accommodate at least one of the three different types of communication satellite payload module and a plurality of the other of the two sizes of communication satellite bus module configured to accommodate at least one other of the three different types of communication satellite payload modules are inventoried.

In embodiments of the invention, each of the inventoried communication satellite payload modules and each of the inventoried communication satellite bus modules are provided with a pre-configured standard interface coupling.

One or more of the inventoried communication satellite payload modules are selected, and the size of communication satellite bus module configured to accommodate the selected communication satellite payload module is likewise selected, according to pre-defined communication satellite parameters. Thereafter, the one or more selected communication satellite payload modules are coupled to the selected communication satellite bus module via the pre-configured standard interface coupling, and the selected communication satellite bus module is, in turn, coupled to a communication satellite launch vehicle according to the pre-defined communication satellite parameters.

This summary is provided to introduce a selection of concepts in simplified form that are further described below in the detailed description. This summary is not intended to identify key features or essential features of the claimed subject matter, nor is it intended to be used to limit the scope of the claimed subject matter.

### BRIEF DESCRIPTION OF THE DRAWINGS

FIG. 1 is a schematic representation of an example of an inventory of a plurality of each of two different sizes of communication satellite bus modules for embodiments of the invention;

FIG. 2 is a schematic representation of an example of an inventory of a plurality of each of three different types of communication satellite payload modules for embodiments of the invention;

FIG. 3 is a schematic representation of an example of one of the inventoried communication satellite payload modules coupled to one of the inventoried communication satellite bus modules via a pre-configured standard interface coupling for embodiments of the invention; and

FIG. 4 is a flow diagram that illustrates an example of the process of making a communication satellite assembly for embodiments of the invention.

### DETAILED DESCRIPTION OF THE INVENTION

Various aspects of the embodiments will now be described. The following description provides specific details for a thorough understanding and enabling description of these examples. Many of these specific details are optional. One skilled in the art will understand, however, that the invention and its various embodiments may be practiced without many of these specific details and options. Additionally, some well-known structures or functions may not be shown or described in detail, so as to avoid unnecessarily obscuring the relevant description.

The terminology used in the description presented below is intended to be interpreted in its broadest reasonable manner, even though it is being used in conjunction with a detailed description of certain specific examples. Certain terms may even be emphasized below; however, any terminology intended to be interpreted in any restricted manner will be overtly and specifically defined as such in this detailed description section. Aspects, features, and elements of the invention and of embodiments of the invention are described throughout the written description and the drawings and claims.

The invention is directed to an improved satellite communication system, infrastructure and method of utilizing and providing the same. The infrastructure and system solve the problems with the solutions described herein by (1) delivering the satellite on an in-orbit and operational basis, (2) delivering a modular communication payload and standard bus which results in rapid satellite manufacture and deployment, (3) offering a cost-effective solution that augments the aforementioned solutions and (4) utilizing existing customer orbital spectrum and radio frequencies so that the service is compatible with the terrestrial infrastructure used by the DoD and other USG end users.

Embodiments of the invention propose an improved satellite communication infrastructure and method of providing same that includes a satellite infrastructure with a standardized bus that handles all control functionality including structural sub-systems, telemetry sub-systems, power sub-systems, thermal control sub-systems and attitude and orbit sub-systems. Different payloads can be manufactured depending on the desired communication frequency band and are created as self-contained modules which receive power from the bus via a standardized interface.

Embodiments of the invention involve pre-selection of multiple-sized buses and multiple types of payloads so that a communication satellite can be available in orbit in a very short period of time should a need arise. In order to do that, embodiments of the invention involve standardization based at least in part on pre-selection of two or more different-sized buses provided by one or more particular sources, although the same or equivalent buses could be secured from other sources.

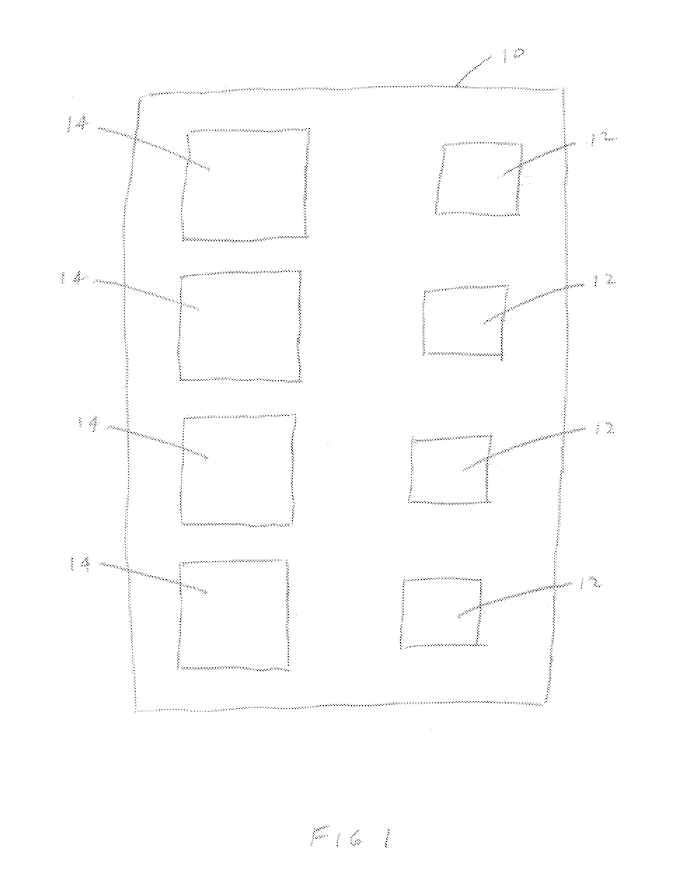

FIG. 1 is a schematic representation of an example of an inventory 10 of a plurality of each of two different sizes of communication satellite bus modules 12 and 14 for embodiments of the invention. Referring to FIG. 1, the two different sizes of inventoried bus modules can include, for example, a smaller size bus module 12 configured to accommodate one or more of particular types of communication satellite payload modules and a larger size bus module 14 configured to accommodate one or more other types of communication satellite payload modules.

In addition to pre-selecting, for example, two different-sized buses, embodiments of the invention involve standardization based on pre-selection of various kinds of payloads that can be stored on a shelf and made immediately available for attachment to an appropriate one of the different-sized buses.

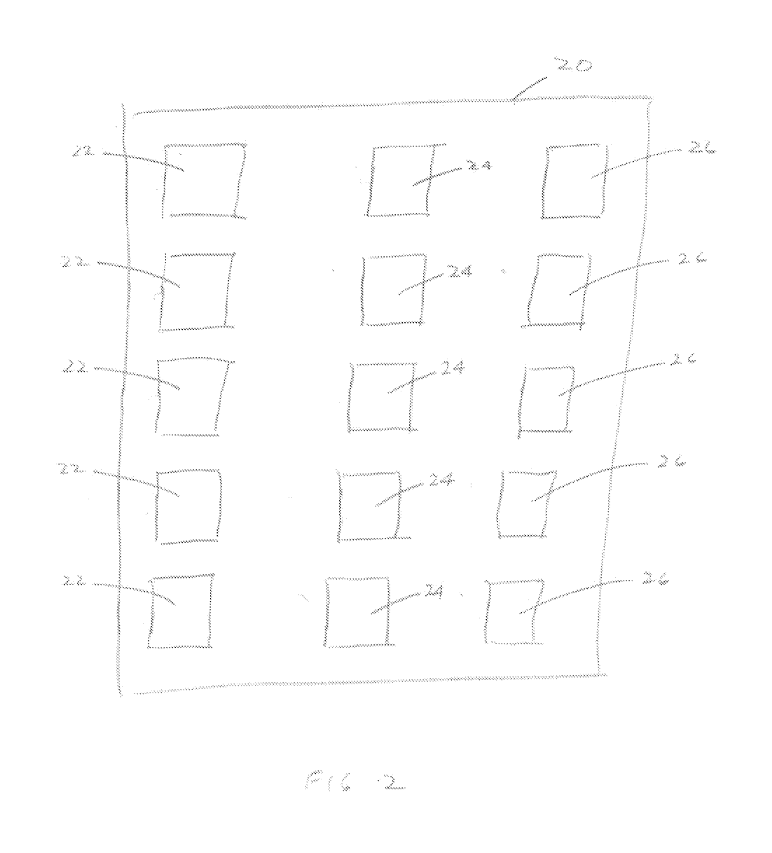

FIG. 2 is a schematic representation of an example of an inventory 20 of a plurality of each of three different types of communication satellite payload modules 22, 24, and 26 for embodiments of the invention. Referring to FIG. 2, the three different types of inventoried payload modules can include, for example, wideband frequency type payloads 22, narrow band frequency type payloads 24, and a combination of wideband and narrow band frequency type payloads 26.

If a commercial satellite operator began construction of a communication satellite today, it would typically require a minimum of twenty-four to twenty-seven months to deploy the satellite in orbit. In order to reduce that time, embodiments of the invention provide one or more pre-selected different-sized buses that can accommodate various different payloads that can be procured in advance and made immediately available to be attached to the appropriate bus.

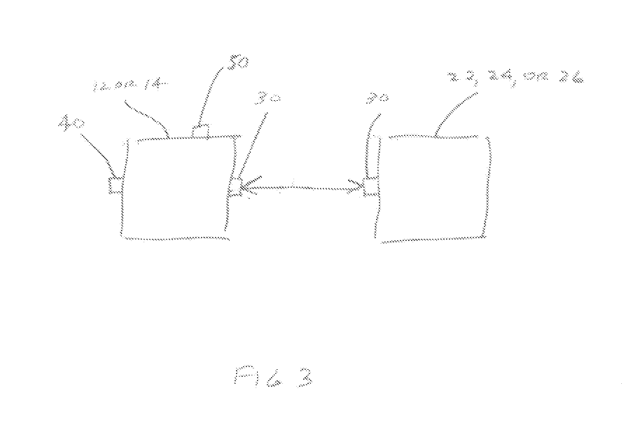

FIG. 3 is a schematic representation of an example of one of the inventoried communication satellite payload modules 22, 24, or 26 coupled to one of the inventoried communication satellite bus modules 12 or 14 via pre-configured standard interface coupling 30 for embodiments of the invention. An advantage of pre-selecting and inventorying multiple different-sized buses, such as bus modules 12 and 14, and various different types of payload, such a payload modules 22, 24 and 26, according to embodiments of the invention is that when a request is received for quick deployment of a communication satellite with a particular payload, if the specified payload is in the inventory, it can be attached to the appropriate bus via the pre-configured standard interface coupling 30 and launched into orbit in significantly less than twenty-four to twenty-seven months.

Further, pre-selecting and inventorying multiple different-sized buses and various different types of payloads according to embodiments of the invention makes it possible to have a communication satellite that can literally be launched virtually on demand by having the satellite with a payload ready at a launch site proximate a suitable launch vehicle that is also inventoried at the launch site. Upon receiving a request, the satellite can be placed on the launch vehicle and launched into orbit.

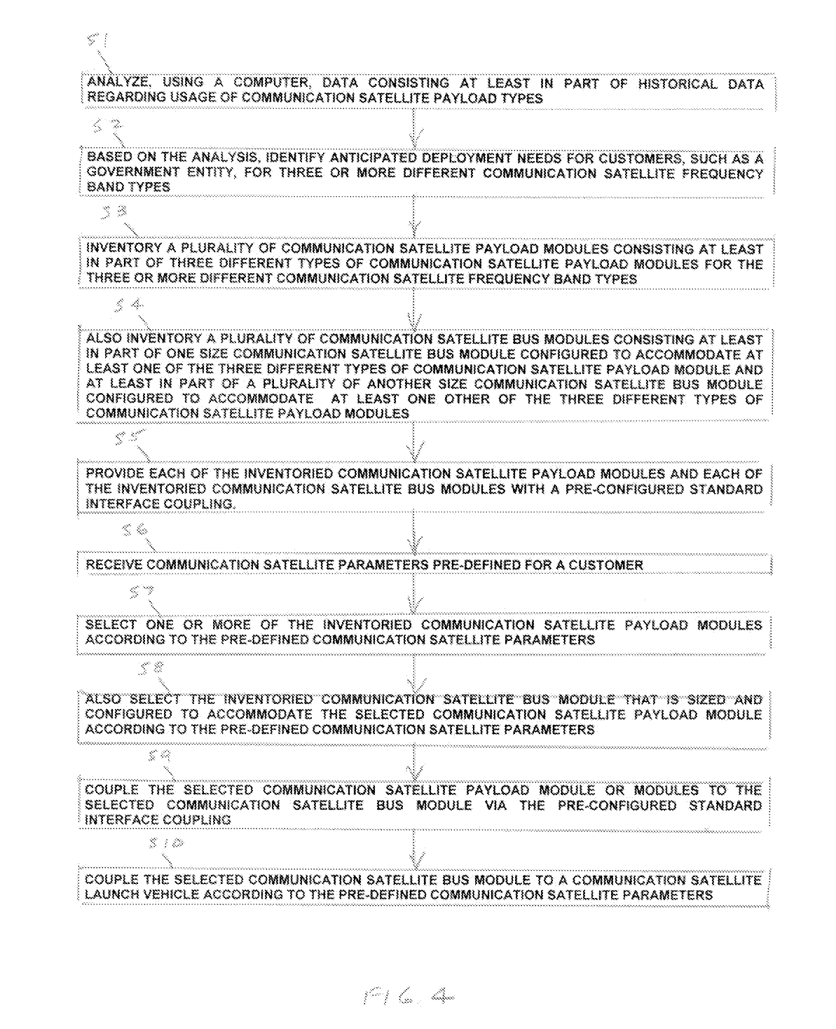

FIG. 4 is a flow diagram that illustrates an example of the process of making a communication satellite assembly for embodiments of the invention. Referring to FIG. 4, at S1, data consisting at least in part of historical data regarding usage of communication satellite payload types is analyzed using a computer. Based on the analysis, at S2, anticipated deployment needs for customers, such as a government entity, for three or more different communication satellite frequency band types are identified, and at S3, a plurality of communication satellite payload modules consisting at least in part of three different types of communication satellite payload modules 22, 24, and 26 for the three or more different communication satellite frequency band types is inventoried.

Referring further to FIG. 4, at S4, a plurality of communication satellite bus modules consisting at least in part of one size communication satellite bus module 12 configured to accommodate at least one of the three different types of communication satellite payload module and at least in part of a plurality of another size communication satellite bus module 14 configured to accommodate at least one other of the three different types of communication satellite payload modules is also inventoried. At S5, each of the inventoried communication satellite payload modules and each of the inventoried communication satellite bus modules is provided with a pre-configured standard interface coupling 30.

Referring again to FIG. 4, at S6, when communication satellite parameters pre-defined for a customer are received, at S7, a selection is made of one or more of the inventoried communication satellite payload modules 22, 24, 26 according to the pre-defined communication satellite parameters, and at S8, a selection is also made of the inventoried communication satellite bus module 12 or 14 that is sized and configured to accommodate the selected communication satellite payload module. At S9, the selected communication satellite payload module or modules are coupled to the selected communication satellite bus module via the pre-configured standard interface coupling, and at S10, the selected communication satellite bus module is, in turn, coupled to a communication satellite launch vehicle.

Embodiments of the invention propose pre-selecting and inventorying a number of different-sized buses, pre-selecting and inventorying multiple different types of payload systems, and also pre-selecting and providing a suitable launch vehicle. Embodiments of the invention further involve pre-selecting and inventorying, for example, multiple satellite launch vehicles, such as three different rockets or boosters which can be used to deploy a satellite into orbit. In an embodiment of the invention, the pre-selected multiple launch vehicles each falls into a different category of launch characteristics.

In an embodiment of the invention, two of the inventoried launch vehicles can be commercially available rockets or boosters and a third can be a rocket or booster available from a government entity, such as the U.S. Air Force. In embodiments of the invention, the pre-selection process can begin with the rocket or booster. In other words, a determination is made based on the launch capacity of the launch vehicle. Thus, according to embodiments of the invention, in pre-selecting the multiple different-sized buses to inventory, it is preferable to pre-select at least two different-sized buses based upon the launch characteristics of the pre-selected different-sized launch vehicles.

The capacity of each category of rocket to launch a satellite to a particular station in orbit is known, which defines a limit on the weight of the satellite, and a decision on the category of rocket is based on how much payload each category can accommodate. With knowledge of the capacity of each category of rocket and the composition, size and weight of payloads for various communication frequency bands, a small satellite payload can be allocated to a correspondingly small capacity category of rocket and a larger satellite payload can be allocated to a correspondingly larger capacity category of rocket.

The launch vehicle and payload pre-selection process for embodiments of the invention involves, for example, pre-selecting at least two standardized bus sizes and at least three different types of payloads optimized according to the capabilities of particular launch vehicles. Pre-selection of buses is, at least in part, frequency dependent. For example, embodiments of the invention may preferably employ a small-sized bus for either one of a narrow band or a wideband payload and a mid- to large sized bus for a combination of both a narrow band and a wideband payload. Further, the payload on the small-sized bus can have one of three or four sets of frequencies for the small satellite. In other words, the small satellite can typically be devoted to a particular band, and the mid-size satellite can typically have payloads operating on different frequencies.

Embodiments of the invention involve analyzing the market to determine what kinds of payloads may be needed and securing and storing payloads anticipated to be needed in the future. An aspect of such analysis can involve, for example, analyzing, using computer hardware and software, data consisting at least in part of historical data regarding usage of different payload types to identify anticipated deployment needs for customers. Thus, instead of simply responding to a request for proposal, embodiments of the invention involve pre-selection and inventorying multiple-sized buses and types of payloads with a price list for launch and delivery of a communications satellite into orbit within a short period of time at the request of a customer.

The use of a standardized bus and a “plug-and-play” payload provides for a modular approach which will result in rapid manufacturing, deployment and launch. Depending on the customer's communication need, a particular payload can be taken “off the shelf” (i.e., from inventory) and quickly mounted on the satellite panel and connected to the bus. If the customer decides, prior to launch, that a different frequency band is needed (e.g. X band), a Ka band payload can be removed and replaced by an X band payload without making any modifications to the bus thus resulting in a much quicker and less expensive deployment.

The bus and payload have the capability to be controlled remotely with separate control devices, which in one embodiment of the invention are laptop computers. One computer communicates with the bus via a first antenna while the other communicates with the payload via a second antenna. Typically, a commercial satellite service provider controls both the bus and the payload, but the invention provides for turning control of the payload, e.g., via the payload control laptop over to the customer while retaining control of positioning the satellite. An aspect of embodiments of the invention provides separate control of the satellite and payload. For example, two control terminals, such as two laptop computers, can be provided with the satellite, one to control positioning of the satellite and the other to control management of the payload. Thus, total management control of the satellite and payload can be given exclusively to the customer.

Another aspect of the invention is the inclusion of space situational awareness functionality on the satellite, which is separate and apart from the satellite attitude sensor system comprising, for example, at least one camera 40 mounted on an exterior portion of the bus module 12 or 14 as illustrated schematically in FIG. 3. In a preferred embodiment, the satellite will include a number of cameras mounted to the outside of the bus which will allow a real time view of the surrounding area which could be several thousand miles in each direction. Additional cameras can be added to increase the field of view. The cameras are capable of recording video (two or three dimensional) or still images and can be controlled to record continuously or at predetermined times.

Once an object, such as another satellite or a piece of space junk, is detected, the video or still images can be evaluated against a database of known space objects in order to identify the object. This functionality can be utilized by satellite users such as the USG to determine the identity and change of location of a variety of objects.

A further embodiment of the invention is directed to a satellite which includes a refueling valve 50 of the bus module 12 or 14 as part of its structure as illustrated schematically in FIG. 3. This valve will allow direct access to the satellite fuel tank in the event that technology is developed that will allow refueling of a satellite in geostationary orbit, for example, for repositioning and/or sustaining or extending the useful life of the satellite. The refueling valve may include a locking mechanism to prevent inadvertent or unauthorized access to the fuel tank.

It is to be understood that the method of making a communication satellite assembly described herein, for example, with respect to FIG. 4 may include the manipulation of signals by a processor and the maintenance of those signals within data structures resident in one or more memory storage devices. For the purposes of this discussion, a process can be generally conceived to be a sequence of computer-executed steps leading to a desired result. While the present invention may comprise a computer program or hardware or a combination thereof which embodies the functions described herein and illustrated, for example, in FIG. 4, it should be apparent that there could be many different ways of implementing the invention in computer programming or hardware design, and the invention should not be construed as limited to any one set of computer program instructions.

While the invention herein disclosed and the best mode contemplated have been described by means of certain specific embodiments of the invention and applications thereof, no matter how detailed the above appears in text, the invention can be practiced in many ways, and numerous modifications and variations can be made thereto by those skilled in the art without departing from the scope of the invention. Details of the processes, devices and systems may vary considerably in their implementation details, while still being encompassed by the invention disclosed herein. This includes the use of the invention in non-government or non-military fields and by non-government or non-military end-users.

In addition, the words “herein,” “above,” “below,” and words of similar import, when used in this application, shall refer to this application as a whole and not to any particular portions of this application. Where the context permits, words in the above detailed description using the singular or plural number may also include the plural or singular number respectively. The word “or,” in reference to a list of two or more items, covers all of the following interpretations of the word: any of the items in the list, all of the items in the list, and any combination of the items in the list.

Further, the above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. Further any specific numbers noted herein are only examples: alternative implementations may employ differing values or ranges. The teachings of the invention provided herein can be applied to other processes, devices and systems, not necessarily the processes, devices and systems described above. The elements and acts of the various embodiments described above can be combined to provide further embodiments.

As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific embodiments disclosed in the specification, unless the above detailed description section explicitly defines such terms. Accordingly, the actual scope of the invention encompasses not only the disclosed embodiments, but also all equivalent ways of practicing or implementing the invention under the claims.

1. A communication satellite assembly, comprising:
at least one communication satellite payload module being selected according to pre-defined communication satellite parameters from an inventory of communication satellite payload modules consisting at least in part of three different types of communication satellite payload modules for three different communication satellite frequency band types, each of said inventoried communication satellite payload modules being provided with a pre-configured standard interface coupling;
one of a first and second size communication satellite bus module configured to accommodate said selected at least one inventoried communication satellite payload module and being selected according to said pre-defined communication satellite parameters from an inventory of communication satellite bus modules consisting at least in part of a plurality of a first size communication satellite bus modules configured to accommodate at least a first of said three different types of communication satellite payload modules and a plurality of a second size communication satellite bus modules configured to accommodate at least a second of said three different types of communication satellite payload modules, each of said inventoried communication satellite bus modules being provided with said pre-configured standard interface coupling;
said at least one selected communication satellite payload module being coupled to said selected communication satellite bus module via said pre-configured standard interface coupling; and
said selected communication satellite bus module being coupled to a communication satellite launch vehicle.

2. The communication satellite assembly of claim 1, wherein said pre-defined communication satellite parameters comprise orbit and frequency band parameters compatible with a terrestrial infrastructure used by a governmental entity.

3. The communication satellite assembly of claim 1, wherein each of said inventoried communication satellite payload modules comprises one or more antennas, amplifiers and transponders.

4. The communication satellite assembly of claim 1, wherein said three different types of communication satellite payload modules further comprise communication satellite payload module types for each of at least three different communication satellite frequency band types consisting of one or more wideband frequency payload types, one or more narrow band frequency payload types, and a combination of one or more wideband and one or more narrow band frequency payload types.

5. The communication satellite assembly of claim 1, wherein each of said inventoried communication satellite bus modules comprises a structural sub-system, a telemetry sub-system, power sub-systems, a thermal control sub-system, and an attitude and orbit sub-system.

6. The communication satellite assembly of claim 1, wherein one size of said first and second size communication satellite bus modules is configured to accommodate at least one communication satellite payload module for either a communication satellite wideband frequency type payload or a communication satellite narrow band frequency type payload and the other size of said first and second size communication satellite bus modules is configured to accommodate at least one communication satellite payload module for each of a communication satellite wideband frequency type and a communication satellite narrow band frequency type.

7. The communication satellite assembly of claim 1, further comprising a communication satellite bus control device for managing the communication satellite bus module and a communication satellite payload module control device for managing the communication satellite payload module, both of said control devices being deployed to a communication satellite customer for exclusive management control of said selected communication satellite bus and payload modules.

8. The communication satellite assembly of claim 7, wherein said communication satellite bus control device comprises a first computing device in wireless communication with the selected communication satellite bus module and wherein said communication satellite payload control device comprises a second computing device in wireless communication with the selected communication satellite payload module.

9. The communication satellite assembly of claim 1, further comprising at least one video camera mounted on an exterior of said selected communication satellite bus module for providing a real time view of an environment surrounding said selected communication satellite bus module.

10. The communication satellite assembly of claim 1, wherein selected said communication satellite bus module further comprises at least one refueling valve allowing direct access to a satellite fuel tank for refueling.

11. The communication satellite assembly of claim 10, wherein said at least one refueling valve further comprises a locking mechanism to prevent inadvertent or unauthorized access to the satellite fuel tank.

12. A method of making a communication satellite assembly, comprising:
analyzing, using a computer, data consisting at least in part of historical data regarding usage of communication satellite payload types to identify anticipated deployment needs for at least three different communication satellite frequency band types;
inventorying a plurality of communication satellite payload modules consisting at least in part of three different types of communication satellite payload modules for said at least three different communication satellite frequency band types;
inventorying a plurality of communication satellite bus modules consisting at least in part of a plurality of a first size communication satellite bus module configured to accommodate at least a first of said three different types of communication satellite payload module and a plurality of a second size communication satellite bus module configured to accommodate at least a second of said three different types of communication satellite payload modules;
providing each of said inventoried communication satellite payload modules and each of said inventoried communication satellite bus modules with a pre-configured standard interface coupling;
selecting according to pre-defined communication satellite parameters at least one of said inventoried communication satellite payload modules;
selecting according to said pre-defined communication satellite parameters one of said first and second size communication satellite bus modules configured to accommodate said selected at least one inventoried communication satellite payload module;
coupling said selected communication satellite payload modules to said selected communication satellite bus module via said pre-configured standard interface coupling; and
coupling said selected communication satellite bus module to a communication satellite launch vehicle.
